(19) United States
(12) Patent Application Publication
(10) Pub. No.: US 2026/0122975 A1
(43) Pub. Date: Apr. 30, 2026

(54) SEMICONDUCTOR DEVICE AND METHOD FOR FORMING THE SAME

(71) Applicant: Winbond Electronics Corp., Taichung City (TW)

(72) Inventor: Kai-Hsiang CHANG, Taichung City (TW)

(21) Appl. No.: 19/003,353

(22) Filed: Dec. 27, 2024

(30) Foreign Application Priority Data
Jul. 8, 2024 (TW) 113125481

(51) Int. Cl. H10D 30/68; H01L 21/28; H10B 41/35; H10D 30/01; H10D 64/01; H10D 64/27; H10D 64/66

(52) U.S. Cl. CPC H10D 30/6891; H10B 41/35; H10D 30/0411; H10D 64/01312; H10D 64/035; H10D 64/518; H10D 64/664

(57) ABSTRACT

A semiconductor device is provided and includes a substrate, a gate structure and a conductive plug. The gate structure is formed in the substrate and includes a conductive layer and an insulating capping layer. The conductive layer has a first portion and a second portion extending in a vertical direction from the upper surface of the first portion, so that a step height is formed between the upper surface of the first portion and the upper surface of the second portion. The insulating capping layer covers the upper surfaces of the first portion and the second portion.

### CROSS REFERENCE TO RELATED APPLICATIONS

This application claims priority of Taiwan Patent Application No. 113125481 filed on Jul. 8, 2024, and entitled “SEMICONDUCTOR DEVICE AND METHOD FOR FORMING THE SAME”, the entirety of which is incorporated by reference herein.

### BACKGROUND OF THE INVENTION

### Field of the Invention

The invention relates to semiconductor technology, and in particular to a semiconductor device that is capable of reducing junction leakage, and a method of forming the same.

### Description of the Related Art

As electronic products and semiconductor devices are scaled down, the manufacturing of semiconductor devices faces some challenges.

For example, in a semiconductor device, the contact plugs of the word lines in the memory array area and the gate contact plugs of the peripheral area are processed in the same process. The fabrication of contact plugs typically involves etching contact openings and filling the contact openings with a conductive material. However, when contact openings are etched in the memory array area and the peripheral area, in order to expose the upper surfaces of the word lines embedded in the substrate, over-etching is likely to occur in the peripheral area.

As a result, the over-etched contact opening extends too deep into the silicon substrate, which easily causes junction leakage when the devices in the peripheral area are in operation. Therefore, the reliability of the semiconductor device may decrease.

### BRIEF SUMMARY OF THE INVENTION

Embodiments of the present invention provide a semiconductor device and a forming method thereof, which can improve the junction leakage of the semiconductor device.

In some embodiments, a semiconductor device is provided. The semiconductor device includes a substrate and a gate line structure formed in the substrate. The gate line structure includes a first conductive layer that has a first portion and a second portion extending in a vertical direction from the upper surface of the first portion, so that a step height is formed between the upper surface of the first portion and the upper surface of the second portion. The gate line structure also includes a first insulating capping layer that covers the upper surface of the first portion and the upper surface of the second portion. The semiconductor device also includes a conductive plug extending in a vertical direction from the inside of the second portion of the first conductive layer and passing through the first insulating capping layer to protrude above the substrate.

In some embodiments, a method of forming a semiconductor device is provided. The method includes providing a substrate, forming a gate opening in the substrate, and forming a first conductive layer that fills the gate opening. The first conductive layer has a recess, the width of the recess is smaller than the width of the gate opening. The first conductive layer includes: a first portion and a second portion extending upward from the upper surface of the first portion along a sidewall of the gate opening, so that a first step height is formed between the upper surface of the first portion and the upper surface of the second portion. In addition, the method includes forming a first insulating capping layer that covers the upper surface of the first portion and the upper surface of the second portion and forming a conductive plug that passes through the first insulating capping layer and extends into the second portion of the first conductive layer.

In some embodiments, a semiconductor device is provided. The semiconductor device includes: a substrate, an isolation structure formed in the substrate, and a word line structure formed in the substrate and partially laterally extending in the isolation structure. The word line structure includes a stepped conductive layer having a first upper surface and a second upper surface lower than the first upper surface, and an insulating capping layer covering the first upper surface and the second upper surface.

### BRIEF DESCRIPTION OF THE DRAWINGS

FIGS. 1A to 1G are cross-sectional views of a semiconductor device at various process stages in accordance with some embodiments.

FIGS. 2A to 2C are cross-sectional views of a semiconductor device at various process stages in accordance with some embodiments.

FIG. 3 is a plan view of a semiconductor device in accordance with some embodiments.

### DETAILED DESCRIPTION OF THE INVENTION

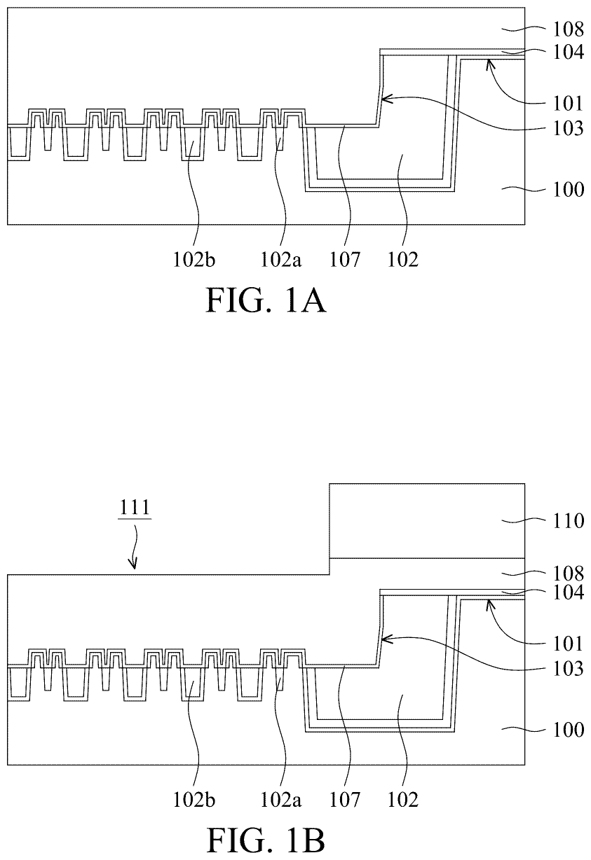

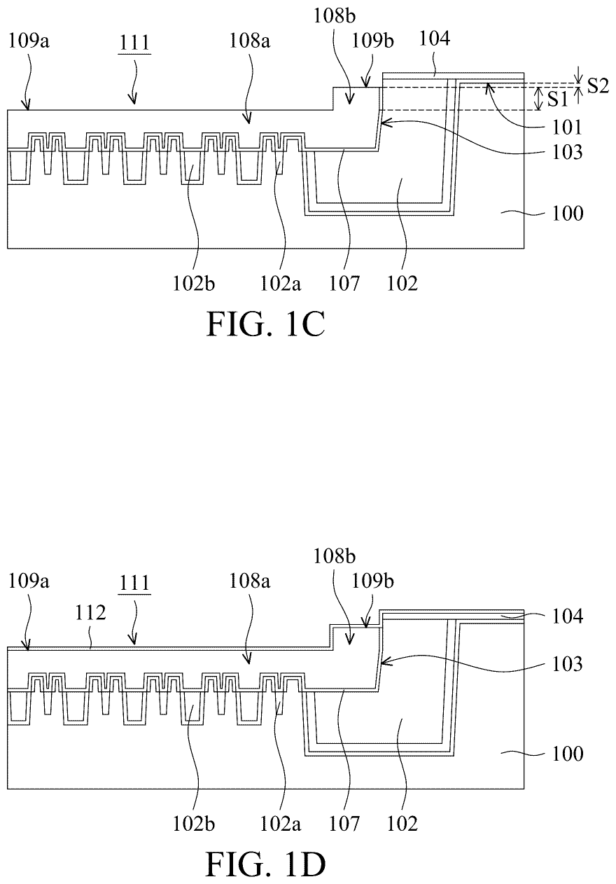

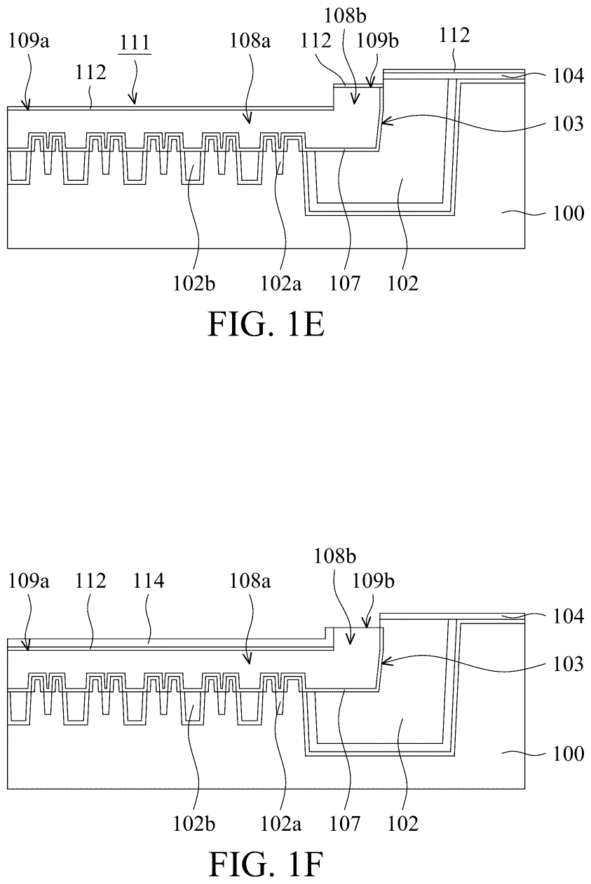

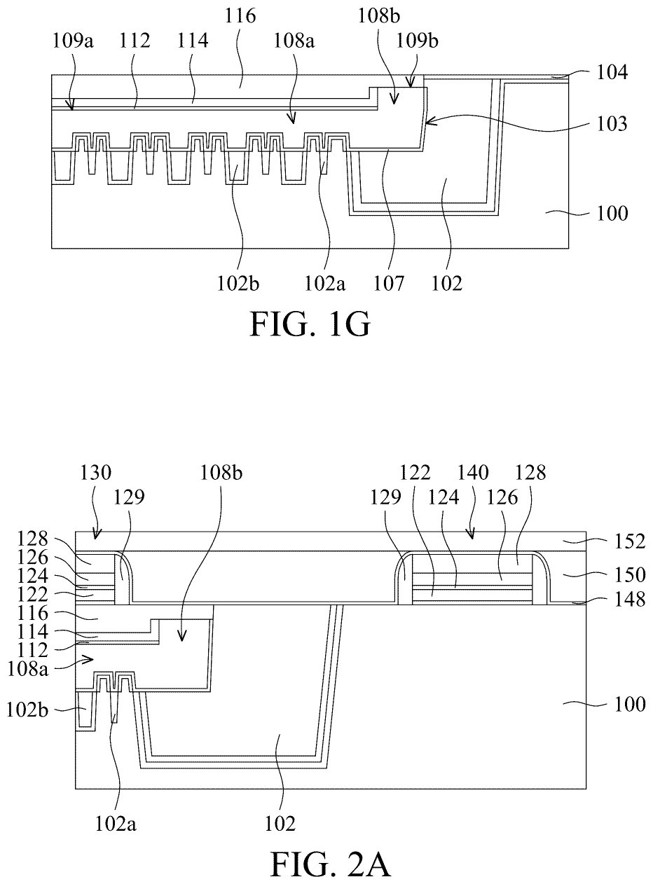

In some embodiments, a semiconductor device can be implemented as a buried gate line structure and used in a semiconductor word line structure. Referring to FIG. 1A, a substrate 100 is provided. The substrate 100 may be a silicon substrate, a silicon-on-insulator (SOI) substrate, or another suitable substrate. The substrate 100 may be doped with P-type or N-type dopants or may be undoped. Afterwards, isolation structures 102, 102a and 102b of different sizes can be formed in the substrate 100 to serve as electrical isolation layers. For example, the isolation structures 102, 102a, and 102b may be referred to as shallow trench isolation structures. The shallow trench isolation structure may include one or more insulating liners that surround the insulating filling layer or may be formed of the insulating filling layer only. For example, the insulating liner and/or the insulating filling layer may include a silicon oxide, a silicon nitride, a silicon oxynitride, a silicon oxycarbide, or the like or combinations thereof. Furthermore, the insulating liner and/or the insulating filling layer may be formed using a chemical vapor deposition (CVD) process, an atomic layer deposition (ALD) process, or another suitable deposition processes.

Afterwards, an insulating layer 104, such as a silicon oxide, is formed on the substrate 100 and the isolation structure 102. The insulating layer 104 may be formed using a CVD process, an ALD process, a thermal oxidation method, or another suitable deposition processes. In some embodiments, the insulating layer 104 may serve as a gate dielectric layer in a gate structure (not shown) that is formed on the substrate 100.

Next, the substrate 100 is patterned to form gate openings 103 in the substrate 100 and a portion of the isolation structure 102 for subsequent formation of a gate structure in each gate opening 103. The patterning of the substrate 100 can be performed using lithography and etching processes (e.g., dry or wet etching processes).

After the gate openings 103 are formed, a first conductive layer 108 is formed on the upper surface 101 of the substrate 100 and fills the gate openings 103. The first conductive layer 108 may include a metal material (e.g., copper, aluminum, tungsten, titanium, tantalum, the like or alloys thereof) or another suitable conductive material. The first conductive layer 108 may be formed using a CVD process, an ALD process, a physical vapor deposition (PVD) process, or another suitable deposition processes. In some embodiments, a barrier layer 107, such as titanium nitride, tantalum nitride, tungsten nitride or the like, is conformally formed on the bottom and sidewalls of the gate opening 103 prior to the formation of the first conductive layer 108. For example, the barrier layer 107 is made of titanium nitride and can be formed using an ALD process. The barrier layer 107 can also be used as an adhesive layer to increase the adhesion between the underlying structure and the conductive layer subsequently formed thereon.

Referring to FIG. 1B, a recess 111 is formed in the first conductive layer 108 located in the gate opening 103. A masking layer, such as a photoresist layer, may be formed over the structure shown in FIG. 1A. Afterwards, the masking layer is patterned using, for example, photolithography and etching processes to form a patterned masking layer 110. Afterwards, for example, an etching process is employed to remove the first conductive layer 108 exposed by the patterned masking layer 110, so as to form the recess 111. In some embodiments, the width of the recess 111 is smaller than the width of the corresponding gate opening 103, so that the sidewalls of the recess 111 do not laterally exceed the sidewalls of the corresponding gate opening 103. Furthermore, the distance between the sidewall of the recess 111 and the corresponding sidewall of the gate opening 103 will be greater than the bottom width of the conductive plug that is subsequently formed on the first conductive layer 108. In some embodiments, the lower surface of recess 111 is located above the upper surface of insulating layer 104. In some other embodiments, the lower surface of the recess 111 is also aligned with or lower than the upper surface 101 of the substrate 100.

Referring to FIG. 1C, the first conductive layer 108 having the recess 111 is etched back. In some embodiments, the patterned masking layer 110 is removed to expose the first conductive layer 108 having the recess 111. Afterwards, an etching process can be used to completely remove the first conductive layer 108 outside the gate opening 103, and simultaneously remove portions of the first conductive layer 108 and the barrier layer 107 in the gate opening 103. As a result, the first conductive layer 108 remaining in the gate opening 103 exposes a portion of the sidewall of the isolation structure 102. That is, a portion of the isolation structure 102 protrudes from the upper surface 109b of the second portion 108b of the first conductive layer 108. Furthermore, since the first conductive layer 108 has the recess 111 before the etching back is performed, the remaining first conductive layer 108 has a stepped profile after the etching back.

More specifically, the first conductive layer 108 remaining in the gate opening 103 includes a first portion 108a and a second portion 108b. The first portion 108a is located at the lower portion of the corresponding gate opening 103. The second portion 108b extends upward from the upper surface 109a of the first portion 108a along the sidewall of the corresponding gate opening 103. As a result, a first step height S1 is formed between the upper surface 109a of the first portion 108a and the upper surface 109b of the second portion 108b, and a second step height S2 is formed between the upper surface of the second portion 108b and the upper surface 101 of the substrate 100. The first conductive layer 108 forms a stepped profile due to the first step height S1 and the second step height S2. Furthermore, the first portion 108a and the second portion 108b of the first conductive layer 108 in the gate line structure extend laterally into the isolation structure 102.

Referring to FIG. 1D, a barrier material 112 is conformally formed on the structure shown in FIG. 1C. The barrier material 112 may be made of titanium nitride, tantalum nitride, tungsten nitride, or the like. For example, the barrier material 112 is made of titanium nitride and can be formed using an ALD process. Next, referring to FIG. 1E, an etching process (e.g., wet etching) is performed on the barrier material 112 to remove the barrier material 112 on the sidewall of the second portion 108b of the first conductive layer 108 and on the sidewall of the isolation structure 102 that is above the sidewall of the second portion 108b of the first conductive layer 108. That is, the vertical portions of the barrier material 112 are removed to leave the horizontal portions of the barrier material 112, thereby exposing a portion of sidewall of the isolation structure 102 and the sidewall of the second portion 108b of the first conductive layer 108.

Referring to FIG. 1F, a second conductive layer 114 is conformally formed on the barrier material 112 on the first portion 108a of the first conductive layer 108, and on the sidewall of the second portion 108b of the first conductive layer 108. The second conductive layer 114 may include conductive material, for example, polysilicon, which can be formed using a CVD process, an ALD process, a PVD process, or another suitable deposition processes. In this case, the barrier material 112 can be used as an adhesive layer to enhance the adhesion between the second conductive layer 114 and the underlying first conductive layer 108.

Next, an etching back process is performed on the second conductive layer 114 to expose the upper surface 109b of the second portion 108b of the first conductive layer 108 and the upper surface of the insulating layer 104, and again expose the sidewall of the isolation structure 102. In some embodiments, the first conductive layer 108, the barrier material 112, and the second conductive layer 114 form a gate electrode layer, where the barrier material 112 and the second conductive layer 114 can be used to adjust the work function of the gate electrode layer. In some embodiments, the gate electrode layer is only formed of the first conductive layer 108 without the barrier material 112 and the second conductive layer 114 on the first conductive layer 108. In some embodiments, as shown in FIG. 1F, the second conductive layer 114 forms an L-shaped structure that is on the first portion 108a of the first conductive layer 108 and covers the sidewall of the second portion 108b. As a result, the gate-induced-drain-leakage (GIDL) of the device can be improved.

Referring to FIG. 1G, a gate line structure is formed in each of the gate openings 103. More specifically, after forming the gate electrode layer (including the first conductive layer 108 having a stepped profile, the barrier material 112 and the second conductive layer 114), an insulating layer (not shown) is formed on the upper surface of the insulating layer 104 and fills each of the gate openings 103 to cover the corresponding gate electrode layer. This insulating layer may include a nitrogen-containing insulating layer, such as silicon nitride, silicon oxynitride, silicon carbonitride, or the like. For example, this insulating layer is a silicon nitride layer, and may be formed using a CVD process, an ALD process, or other suitable deposition processes.

Afterwards, a removal process is performed on the insulating layer to expose the upper surface of the insulating layer 104, and a first insulating capping layer 116 is then formed in the gate opening 103 to cover the corresponding gate electrode layer. For example, the removal process may include a chemical mechanical polishing process, a dry etching or wet etching process, or other similar planarization or etching processes. In some embodiments, the first insulating capping layer 116 and the underlying gate electrode layer form a buried gate line structure. The buried gate line structure can be used as a word line structure in the semiconductor device. The first insulating capping layer covers the upper surface 109a of the first portion 108a and the upper surface 109b of the second portion 108b of the first conductive layer 108 in the gate line structure. The barrier material 112 and the second conductive layers 114 in the gate line structure are formed between the first conductive layer 108 and the first insulating capping layer 116.

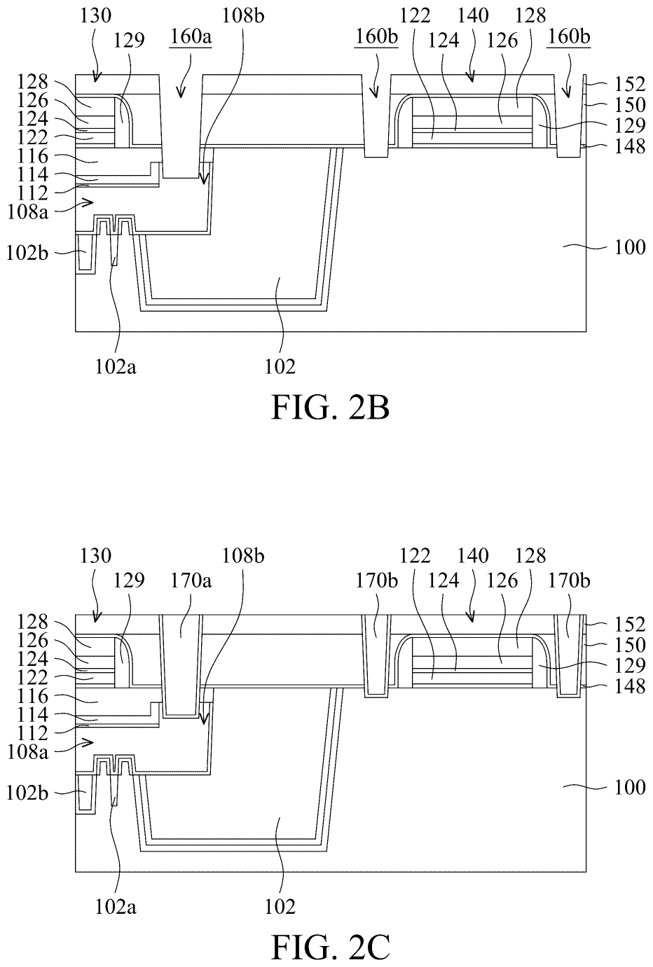

FIGS. 2A to 2C are cross-sectional views of a semiconductor device showing the buried gate line structure in FIG. 1G at various stages of subsequent processes. Referring to FIG. 2A, a structure as shown in FIG. 1G is provided. For purposes of simplicity and clarity, FIG. 2A illustrates a portion of the structure shown in FIG. 1G. In some embodiments, the portion of the substrate 100 corresponding to the gate line structure is the array area, and the peripheral area corresponds to the laterally extending portion of the substrate 100 in FIG. 2A.

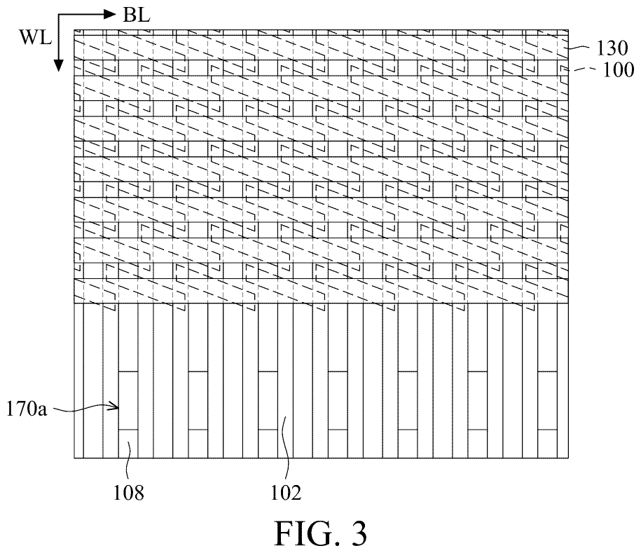

Conventional MOS processes may be used to form one or more gate line structures 130 (also referred to as stacked structures) in the array area of the semiconductor device, and one or more gate line structures 140 (also referred to as stacked structures) are simultaneously formed in the peripheral area of the semiconductor device. The gate line structure 130 and the gate line structure 140 have the same or similar structure. For example, the gate line structure 130 and the gate line structure 140 each have a fourth conductive layer 122, a fifth conductive layer 124 formed on the fourth conductive layer 122, and a sixth conductive layer 126 formed on the fifth conductive layer 124, and a second insulating capping layer 128 formed on the sixth conductive layer 126. In some embodiments, the gate line structure 130 is formed on the first insulating capping layer 116 and serves as a bit line structure in the semiconductor device. The gate line structure 140 is formed over the substrate 100 corresponding to the peripheral area in the semiconductor device and serves as a control gate structure in the semiconductor device. Referring to FIG. 3, which illustrates a plan view of the configuration of the bit line structures and the word line structures shown in the structure shown in FIG. 2A. For purposes of simplicity and clarity, FIG. 3 does not illustrate all of the features shown in FIG. 2A. As shown in FIG. 3, the extending direction WL of the word line structure (including the first conductive layer 108) may be perpendicular to the extending direction BL of the bit line structure. The active area below the first conductive layer 108 and formed by the substrate 100 has a stripe-shaped pattern, as viewed from a top-view perspective, and its direction is different than the direction WL and the direction BL.

The material and formation method of the fourth conductive layer 122 may be the same or similar to those of the second conductive layer 114. For example, the fourth conductive layer 122 is made of polysilicon. The material and formation method of the fifth conductive layer 124 may be the same or similar to those of the barrier material 112. For example, the fifth conductive layer 124 is made of titanium nitride. The material and formation method of the sixth conductive layer 126 may be the same or similar to those of the first conductive layer 108. For example, the sixth conductive layer 126 is made of tungsten metal. Similarly, the material and formation method of the second insulating capping layer 128 may be the same or similar to those of the first insulating capping layer 116. For example, the second insulating capping layer 128 is made of silicon nitride.

After forming the gate line structures 130 and 140, spacers 129 may be formed on two opposite sides of the gate line structures 130 and 140. Next, a first etch stop layer 148, an interlayer dielectric (ILD) layer 150, and a second etch stop layer 152 may be successively formed. As shown in FIG. 2A, the first etch stop layer 148 conformally covers the gate line structures 130 and 140, the spacers 129, the isolation structure 120, and the substrate 100. The ILD layer 150 surrounds the gate line structures 130 and 140. The second etch stop layer 152 is formed on the first etch stop layer 148 above the gate line structures 130 and 140 and on the upper surface of the ILD layer 150.

Next, referring to FIG. 2B, contact openings 160a and 160b are formed. The contact opening 160a corresponds to the array area and extends into the second portion 108b of the first conductive layer 108 through the second etching stop layer 152, the ILD layer 150, the first etching stop layer 148, and the first insulating capping layer 116. Furthermore, the contact opening 160b corresponds to the peripheral area and extends into the substrate 100 through the second etching stop layer 152, the ILD layer 150, and the first etching stop layer 148. For example, the contact openings 160a and 160b may be formed by photolithography and etching processes.

It should be noted that the contact openings 160a and 160b are formed in the same etching process. After etching through the first etch stop layer 148, the contact opening 160a needs to pass through the first insulating capping layer 116 so as to extend into the second portion 108b of the first conductive layer 108, and the contact opening 160b needs to extend into the substrate 100. Therefore, the contact openings 160a and 160b have different depths due to the etching selectivity. Furthermore, in order to ensure that the contact opening 160a extends into the second portion 108b of the first conductive layer 108, over-etching may occur in the peripheral area, causing the contact opening 160b to have an undesired depth. As a result, junction leakage may easily occur in the semiconductor device, resulting in reduced performance and/or reliability of the semiconductor device. However, the word line structure in the embodiments has a stepped gate electrode layer (including the first portion 108a and the second portion 108b of the first conductive layer 108). Therefore, since the level of the upper surface of the second portion 108b of the first conductive layer 108 can be closer to the level of the upper surface 101 of the substrate than the level of the upper surface of the flat gate electrode layer, the risk of over-etching occurring in the peripheral area can be mitigated or completely eliminated.

Referring to FIGS. 2C and 3, in some embodiments, conductive plugs 170a and 170b are formed in the contact openings 160a and 160b, respectively (not shown in FIG. 3). As a result, the conductive plug 170a passes through the first insulating capping layer 116 and extends into the underlying second portion 108b of the first conductive layer 108, so that the conductive plug 170a is electrically connected to the word line structure. In one embodiment, the bottom of the conductive plug 170a is higher than the top of the first portion 108a of the first conductive layer 108. The conductive plug 170b extends into the substrate 100 in the peripheral area, serves as a source/drain plug, and forms a control transistor with the control gate structure (i.e., the gate line structure 140).

According to the foregoing embodiments, since the first portion 108a and the second portion 108b of the first conductive layer 108 in the word line structure form a gate electrode layer with a stepped profile, the level of the uppermost surface of the gate electrode layer can be closer to the level of the upper surface 101 of the substrate than the level of the upper surface of the flat gate electrode layer. Therefore, the risk of over-etching in the peripheral area can be mitigated or completely eliminated during the formation of the conductive plug. As a result, the occurrence of junction leakage in the semiconductor device can be effectively reduced, thereby improving the performance and/or reliability of the semiconductor device.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor device, comprising:
a substrate;
a gate line structure formed in the substrate, comprising:
a first conductive layer having a first portion and a second portion extending in a vertical direction from an upper surface of the first portion, so that a step height is formed between the upper surface of the first portion and an upper surface of the second portion; and
a first insulating capping layer covering the upper surface of the first portion and the upper surface of the second portion; and
a conductive plug extending in a vertical direction from an inside of the second portion of the first conductive layer and passing through the first insulating capping layer to protrude above the substrate.

2. The semiconductor device as claimed in claim 1, wherein the gate line structure further comprises:
a second conductive layer formed on the first portion and covering a sidewall of the second portion.

3. The semiconductor device as claimed in claim 2, wherein the gate line structure further comprises:
a barrier material formed between the first conductive layer and the second conductive layer.

4. The semiconductor device as claimed in claim 1, further comprising:
a stacked structure formed on the first insulating capping layer.

5. The semiconductor device as claimed in claim 4, wherein a first extending direction of the gate line structure is different than a second extending direction of the stacked structure.

6. The semiconductor device as claimed in claim 4, wherein the gate line structure is a word line structure, and the stacked structure is a bit line structure.

7. The semiconductor device as claimed in claim 1, wherein a bottom of the conductive plug is higher than a top of the first portion.

8. The semiconductor device as claimed in claim 1, further comprising:
an isolation structure formed in the substrate, wherein the first portion and the second portion of the first conductive layer in the gate line structure laterally extend into the isolation structure.

9. A method for forming a semiconductor device, comprising:
providing a substrate;
forming a gate opening in the substrate;
forming a first conductive layer that fills the gate opening, wherein the first conductive layer has a recess, wherein a width of the recess is smaller than a width of the gate opening, and wherein the first conductive layer comprises:
a first portion; and
a second portion extending upward from an upper surface of the first portion and along a sidewall of the gate opening, so that a first step height is formed between the upper surface of the first portion and an upper surface of the second portion;
forming a first insulating capping layer that covers the upper surface of the first portion and the upper surface of the second portion; and
forming a conductive plug that passes through the first insulating capping layer and extends into the second portion of the first conductive layer.

10. The method as claimed in claim 9, further comprising:
before forming the first insulating capping layer, forming a second conductive layer on the first portion and covering a sidewall of the second portion.

11. The method as claimed in claim 10, further comprising forming a stacked structure over the gate line structure, wherein the stacked structure comprises:
a fourth conductive layer on the first insulating capping layer;
a fifth conductive layer on the fourth conductive layer;
a sixth conductive layer on the fifth conductive layer; and
a second insulating capping layer on the sixth conductive layer.

12. The method as claimed in claim 11, wherein the fourth conductive layer is made of polysilicon, the fifth conductive layer is made of titanium nitride, and the sixth conductive layer is made of tungsten metal.

13. The method as claimed in claim 11, wherein the gate line structure serves as a word line structure, and the stacked structure serves as a bit line structure.

14. The method as claimed in claim 9, further comprising:
forming an isolation structure in the substrate, wherein the first portion and the second portion of the first conductive layer in the gate opening laterally extend into the isolation structure.

15. The method as claimed in claim 9, further comprising:
forming the first conductive layer on the upper surface of the substrate; and
etching back the first conductive layer to remove the first conductive layer outside the gate opening.

16. The method as claimed in claim 15, wherein after etching back the first conductive layer, a portion of the isolation structure protrudes from the upper surface of the second portion of the first conductive layer.

17. The method as claimed in claim 16, wherein a second step height is formed between the upper surface of the second portion and the upper surface of the substrate.

18. A semiconductor device, comprising:
a substrate;
an isolation structure formed in the substrate; and
a word line structure formed in the substrate and partially laterally extending into the isolation structure, comprising:
a stepped conductive layer having a first upper surface and a second upper surface lower than the first upper surface; and
an insulating capping layer covering the first upper surface and the second upper surface.

19. The semiconductor device as claimed in claim 18, further comprising:
a conductive plug passing through the insulating capping layer and extending below the first upper surface, wherein a bottom of the conductive plug is higher than the second upper surface.

20. The semiconductor device as claimed in claim 18, further comprising:
a bit line structure formed on the insulating capping layer.
